(19) United States
(12) Patent Application Publication
(10) Pub. No.: US 2026/0253848 A1
(43) Pub. Date: Aug. 27, 2026

(54) METAL DEPOSITION USING PULSED VOLTAGE

(71) Applicant: Applied Materials, Inc., Santa Clara, CA (US)

(72) Inventors: Leonid DORF, San Jose, CA (US); Shouyin ZHANG, Santa Clara, CA (US); Sireesh ADIMADHYAM, Santa Clara, CA (US); William R. JOHANSON, JR., Gilroy, CA (US); Evgeny KAMENETSKIY, Santa Clara, CA (US); Shane LAVAN, Palo Alto, CA (US); Suhas UMESH, Santa Clara, CA (US); Viacheslav PLOTNIKOV, San Jose, CA (US)

(21) Appl. No.: 19/548,731

(22) Filed: Feb. 24, 2026

Related U.S. Application Data
(60) Provisional application No. 63/763,248, filed on Feb. 25, 2025.

(51) Int. Cl. H01J 37/32; C23C 16/06; C23C 16/503; C23C 16/505; C23C 16/515

(52) U.S. Cl. CPC H01J 37/32715; C23C 16/06; C23C 16/503; C23C 16/505; C23C 16/515; H01J 37/32146; H01J 37/32449; H01J 2237/2007; H01J 2237/332

(57) ABSTRACT

Embodiments of the disclosure include a processing chamber assembly that comprises: a chamber comprising a substrate-support assembly; a pulsed voltage generator comprising an output connection that is electrically coupled to a plurality of biasing electrodes embedded within the substrate-support assembly; and one or more chucking modules, wherein a chucking module of the one or more chucking modules comprises a direct-current voltage supply that is electrically coupled to one of the plurality of biasing electrodes through a corresponding bias compensation module that comprises a plurality of passive electrical components.

### CROSS-REFERENCE TO RELATED APPLICATIONS

This application claims the benefit of U.S. provisional patent application Ser. No. 63/763,248, filed Feb. 25, 2025, which is herein incorporated by reference.

### BACKGROUND

### Field

Embodiments of the present disclosure generally relate to substrate processing methods and apparatus. More specifically, embodiments of the present disclosure relate to an apparatus and methods of biasing a substrate during plasma processing.

### Description of the Related Art

Reliably producing high aspect ratio features is one of the key technology challenges for the next generation of semiconductor devices. One method of forming high aspect ratio features uses multistep deposition processes that require both biased and unbiased substrate biasing schemes during different phases of the deposition process. During the biased substrate portion of a deposition process ions generated in a plasma bombard a material formed on a surface of a substrate to improve a deposited film's properties and/or reshape portions of the deposited film layer formed on a surface of a substrate.

Processes used to form the next generation of semiconductor devices will include physical vapor deposition (PVD), plasma enhanced atomic layer deposition (PEALD), or plasma enhanced chemical vapor deposition (PECVD) techniques to deposit thin films of various metals and metal alloys within the various high aspect ratio features formed in the substrate. Conventional processes have typically used radio frequency (RF) substrate biasing techniques during portions of the deposition process to etch and/or reshape the deposited layer formed on the surface of the substrate. In conventional plasma processes that utilize an RF biasing scheme, the IEDF will typically include two peaks, which are formed at a low and a high energy and some ion population that has energies that are in between the two peaks, and thus will not form a desired mono-energetic IEDF ion distribution. Moreover, conventional substrate biasing techniques provided during a PEALD, PECVD or PVD deposition process can cause damage to the deposited layer and underlying layers of the substrate, particularly when high-energy ions are used to enhance the deposition rate and/or morphology of the deposited film. This damage can lead to poor step coverage and other defects, which can compromise the performance and reliability of the device. Also, in PVD deposition applications, high energy ions that are delivered to the surface of the substrate can lead to poor deposition bottom coverage due the ballistic nature of the interaction of the high energy ions with the surface of the substrate. To minimize the amount of damage and poor bottom coverage issues it is often desirable to reduce the substrate bias voltage during portion of the plasma process to reduce the energy of the ions formed in the plasma. In one example, low ion energies are often desired during plasma processing to prevent damage to some of the underlying fragile materials (e.g., low-k materials) and fragile device structures formed on exposed regions of the substrate. However, it has been found that conventional substrate biasing hardware are not able to control the substrate bias voltage applied at low voltages during processing. The lack of control of the substrate bias voltage at low bias voltages can lead to substrate-to-substrate deposited film property characteristic(s) and film morphology variability.

Another complication with forming the next generation of semiconductor devices is the need during some stages of plasma assisted deposition process to complete non-plasma based steps processes that require good thermal contact and thermal control of the substrate that is positioned on a substrate supporting surface of a substrate support. In an effort to assure good thermal contact between the substrate and the substrate support surface of a substrate support during a non-plasma based deposition processing step it is common for a bipolar electrostatic chuck to be used to generate a “chucking force” to hold the substrate to the substrate supporting surface. However, during plasma-based steps of a deposition process, applying a pulsed-voltage bias to multiple biasing/chucking electrodes can create uneven charge distributions at the substrate and biasing electrodes, which affect the uniformity of the electrostatic chucking force. This may lead to substrate bending and an uneven temperature profile due to differing thermal contact between different regions of the substrate, which will adversely affect deposition process uniformity across its surface.

Therefore, there is a need for an apparatus and method that can provide improved deposited film properties, such as good bottom coverage and film uniformity, while creating a balanced chucking force across the substrate.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of disclosure include a processing chamber assembly, comprising: a chamber comprising a substrate-support assembly; one or more pulsed voltage generators that each comprise an output connection that is electrically coupled to a plurality of biasing electrodes embedded within the substrate-support assembly; and one or more chucking modules, wherein each chucking module of the one or more chucking modules comprises a direct-current voltage supply that is electrically coupled to one of the plurality of biasing electrodes through a corresponding bias compensation module. The bias compensation module can include a plurality of passive electrical components, wherein the plurality of passive components comprises a diode, a plurality of resistors, and a capacitor.

Embodiments of disclosure include a plasma processing method, comprising: electrostatically chucking a substrate to a substrate supporting surface of a substrate support for a first period of time by applying a first bias voltage to a first biasing electrode and applying a second bias voltage to a second biasing electrode by use of one or more direct-current voltage supplies, wherein the first bias voltage and the second bias voltage are different, the substrate supporting surface is disposed within a processing region of a processing chamber, and the first biasing electrode and the second biasing electrode are disposed within the substrate support. Then electrostatically chucking the substrate to the substrate supporting surface for a second period of time by applying a third bias voltage to the first biasing electrode and the second biasing electrode by use of the one or more direct-current voltage supplies; and establishing a first voltage waveform at the first biasing electrode and a second voltage waveform at the second biasing electrode while the third bias voltage is applied to the first biasing electrode and the second biasing electrode. The plasma processing method can further include dechucking the substrate after establishing the first voltage waveform at the first biasing electrode and the second voltage waveform at the second biasing electrode, wherein dechucking comprises: applying a fourth bias voltage to the first biasing electrode and applying a fifth bias voltage to the second biasing electrode by use of the one or more direct-current voltage supplies, wherein a magnitude of the fourth bias voltage and a magnitude of the fifth bias voltage are less than a magnitude of the third bias voltage or equal to zero.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a cross-sectional view of a processing chamber, according to one or more embodiments described herein.

FIG. 2A illustrates an example of a monoenergetic ion energy distribution function (IEDF) formed with a plasma formed within a processing chamber, according to one or more embodiments.

FIG. 2B illustrates a voltage waveform that may be applied to bipolar electrodes within an electrostatic chuck (ESC) within a plasma processing chamber by a pulse voltage (PV) source, according to one or more embodiments.

FIG. 2C is a schematic cross-sectional view of a physical vapor deposition processing chamber during plasma processing, according to one or more embodiments described herein.

FIG. 2D is a schematic cross-sectional view of a physical vapor deposition processing chamber that includes a bipolar ESC, according to one or more embodiments described herein.

FIG. 2E is a schematic cross-sectional view of a physical vapor deposition processing chamber that includes a bipolar ESC and high-voltage modules that are used to bias the electrodes in the bipolar ESC, according to one or more embodiments described herein.

FIG. 2F is a schematic cross-sectional view of a physical vapor deposition processing chamber that includes a bipolar ESC, high-voltage modules, bias compensation modules (BCMs), blocking capacitors, and bypass resistor that are coupled to portions of a circuit formed between the output of the PV generator and chucking electrodes, according to one or more embodiments described herein.

FIG. 2G is a schematic cross-sectional view of a physical vapor deposition processing chamber that includes a bipolar ESC, high-voltage modules, bias compensation modules (BCMs), blocking capacitors, a bypass resistor, and voltage dividers, which are coupled to a fast-ADC, that are each coupled to portions of a circuit formed between the output of the PV generator and chucking electrodes, according to one or more embodiments described herein.

FIG. 2H is a diagram illustrating a method of processing a substrate by delivering a pulsed-voltage (PV) waveform to one or more electrodes disposed in a substrate support, according to one or more embodiments described herein.

FIG. 2I illustrates voltage waveforms that may be applied to bipolar electrodes within an electrostatic chuck (ESC) within a plasma processing chamber by a pulse voltage (PV) source, according to one or more embodiments.

FIG. 2J illustrates data collected as voltage waveforms are applied to bipolar electrodes within an electrostatic chuck (ESC) within a plasma processing chamber by a pulse voltage (PV) source, according to one or more embodiments.

FIG. 2K illustrates data collected as voltage waveforms are applied to bipolar electrodes within an electrostatic chuck (ESC) within a plasma processing chamber by a pulse voltage (PV) source, according to one or more embodiments.

FIG. 3A1 illustrates a cross-sectional view of an example of a processing chamber that includes a bipolar electrostatic chuck configuration, according to one or more embodiments described herein.

FIG. 3A2 illustrates a cross-sectional view of a first example of a processing chamber that includes a first monopolar electrostatic chuck configuration, according to one or more embodiments described herein.

FIG. 3A3 illustrates a cross-sectional view of a second example of a processing chamber that includes a second monopolar electrostatic chuck configuration, according to one or more embodiments described herein.

FIG. 3B1 illustrates a cross-sectional view of an example of a processing chamber that includes a bipolar electrostatic chuck configuration, according to one or more embodiments described herein.

FIG. 3B2 illustrates a cross-sectional view of an example of a processing chamber that includes a monopolar electrostatic chuck configuration, according to one or more embodiments described herein.

FIG. 3C illustrates a cross-sectional view of a third example of a processing chamber, according to one or more embodiments described herein.

FIG. 4A illustrates a voltage waveform that may be applied to an electrode of a processing chamber by a pulse voltage (PV) source, according to one or more embodiments.

FIG. 4B illustrates a voltage waveform that is established on a substrate due to voltage waveforms applied to a first electrode and a second electrode disposed within a substrate support of a processing chamber, according to one or more embodiments of the disclosure.

FIG. 4C illustrates a voltage waveform that is established on a substrate due to differing voltage waveforms applied to a first electrode and a second electrode disposed within a substrate support of a processing chamber, according to one or more embodiments of the disclosure.

FIG. 4D illustrates a voltage waveform that is established on a substrate due to differing voltage waveforms applied to a first electrode and a second electrode disposed within a substrate support of a processing chamber, according to one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to plasma processing techniques, such as metal deposition processes. More specifically, embodiments of the present disclosure relate to an apparatus and method of delivering pulsed voltage (PV) waveforms to one or more electrodes disposed within a substrate support during one or more phases of a deposition process. In some embodiments, pulsed voltage waveforms are established at one or more biasing electrodes embedded within a substrate support that is disposed within a processing region of a physical vapor deposition (PVD) chamber. During at least one portion of a plasma processing operation, pulsed voltage waveforms at the biasing electrodes are configured to produce a desired substrate voltage waveform and a voltage across a plasma sheath formed over the surface of the substrate.

Embodiments of the present disclosure further relate to techniques for establishing good thermal contact between the substrate and the substrate-facing surface of a substrate support during both plasma and non-plasma containing plasma processing steps. More specifically, embodiments of the present disclosure relate to an apparatus and method of generating an electrostatic chucking force to hold the substrate to the substrate-facing surface of a substrate support using a bipolar electrostatic chuck, DC voltage supplies, and a special electrical circuit. The apparatus and methods described herein are configured to improve thermal contact between the substrate supporting surface of the ESC and the substrate during plasma processing compared to conventional ESC designs and substrate chucking sequences.

### Processing Chamber Examples

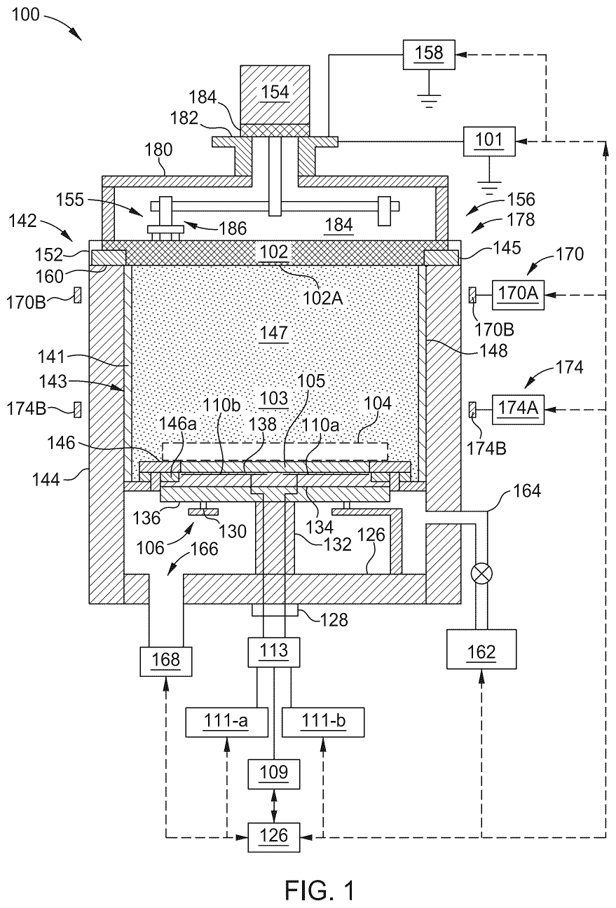

FIG. 1 illustrates a cross-sectional view of one example of a processing chamber 100. The processing chamber 100 includes an upper process assembly 142, a process kit 143, and a substrate-support assembly 106, which are all configured to process a substrate 105 disposed in a processing region 147. The process kit 143 includes a grounded shield 141, a deposition ring 146a, and a cover ring 146. In the version shown, the processing chamber 100 comprises a sputtering chamber, also called a physical vapor deposition (PVD) chamber, capable of depositing a single or multi-compositional material from a sputtering target 102 on the substrate 105. The processing chamber 100 may also be used to deposit aluminum (Al), copper (Cu), nickel (Ni), platinum (Pt), hafnium (Hf), silver (Ag), chrome (Cr), gold (Au), molybdenum (Mo), silicon (Si), ruthenium (Ru), tantalum (Ta), tantalum nitride (TaN), tantalum carbide (TaC), titanium nitride (TiN), tungsten (W), tungsten nitride (WN), lanthanum (La), alumina (AlOₓ), lanthanum oxides (LaOₓ), nickel platinum alloys (NiPt), and titanium (Ti), and or combination thereof.

The processing chamber 100 includes a chamber body 144 having sidewalls 148, a bottom wall 149, and the upper process assembly 142 that enclose the processing region 147 or plasma zone. The chamber body 144 is typically fabricated from welded plates of stainless steel or a unitary block of aluminum. In some embodiments, the sidewalls comprise aluminum and the bottom portion of the chamber includes one or more walls that are formed from a stainless steel plate. The sidewalls 148 generally contain a slit valve (not shown) to provide for entry and egress of a substrate 105 from the processing chamber 100. Components in the upper process assembly 142 of the processing chamber 100 in cooperation with the grounded shield 141, substrate-support assembly 106 and cover ring 146 confine the plasma formed in the processing region 147 to the region above the substrate 105.

The substrate-support assembly 106 is supported from the bottom wall 149 of the processing chamber 100. The substrate-support assembly 106 supports the deposition ring 146a along with the substrate 105 during processing. The substrate-support assembly 106 is coupled to the bottom wall 149 of the processing chamber 100 by a lift mechanism 128, which is configured to move the substrate-support assembly 106 between an upper processing position and lower transfer position. Additionally, in the lower transfer position, lift pins 130 are moved through the substrate-support assembly 106 to position the substrate a distance from the substrate-support assembly 106 to facilitate the exchange of the substrate with a substrate transfer mechanism disposed exterior to the processing chamber 100, such as a single blade robot (not shown). A bellows 132 is typically disposed between the substrate-support assembly 106 and the bottom wall 149 to isolate the processing region 147 from the interior of the substrate-support assembly 106 and the exterior of the chamber.

The substrate-support assembly 106 generally includes a substrate support 134 sealingly coupled to a platform housing 136. The platform housing 136 is typically fabricated from a metallic material such as stainless steel or aluminum. A cooling plate (not shown) is generally disposed within the platform housing 136 enabling thermal regulation of the substrate support 134.

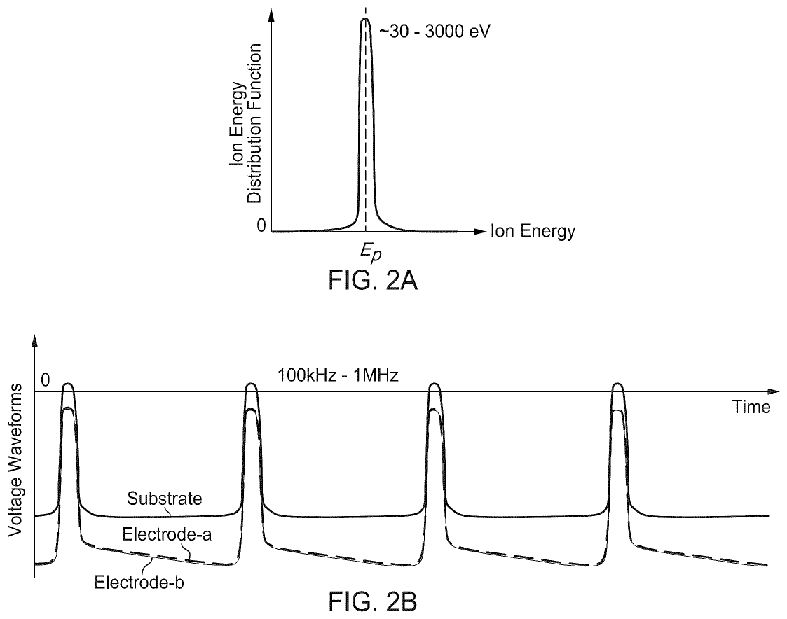

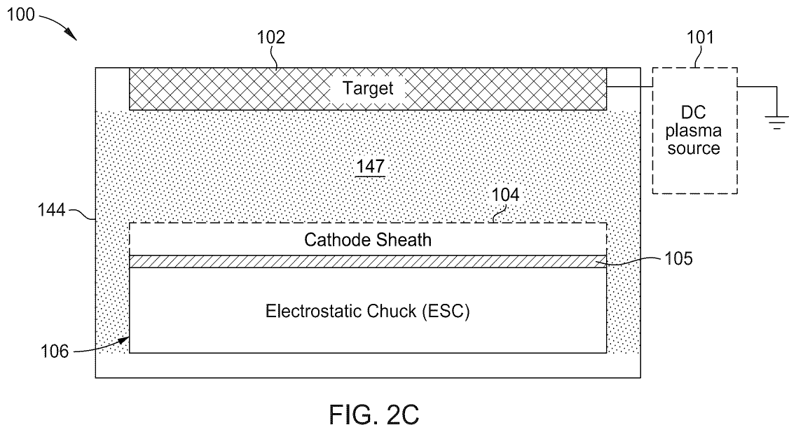

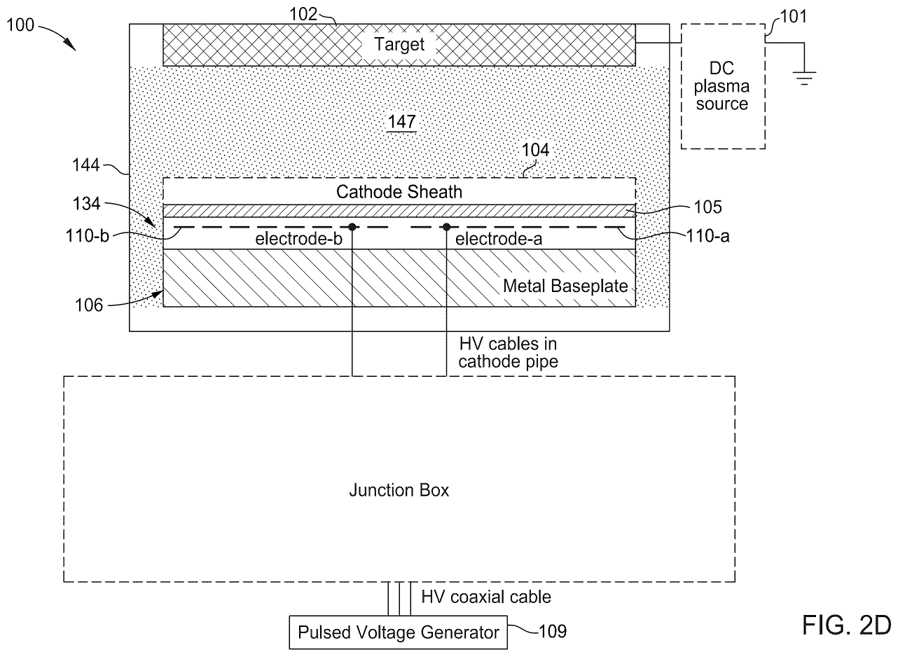

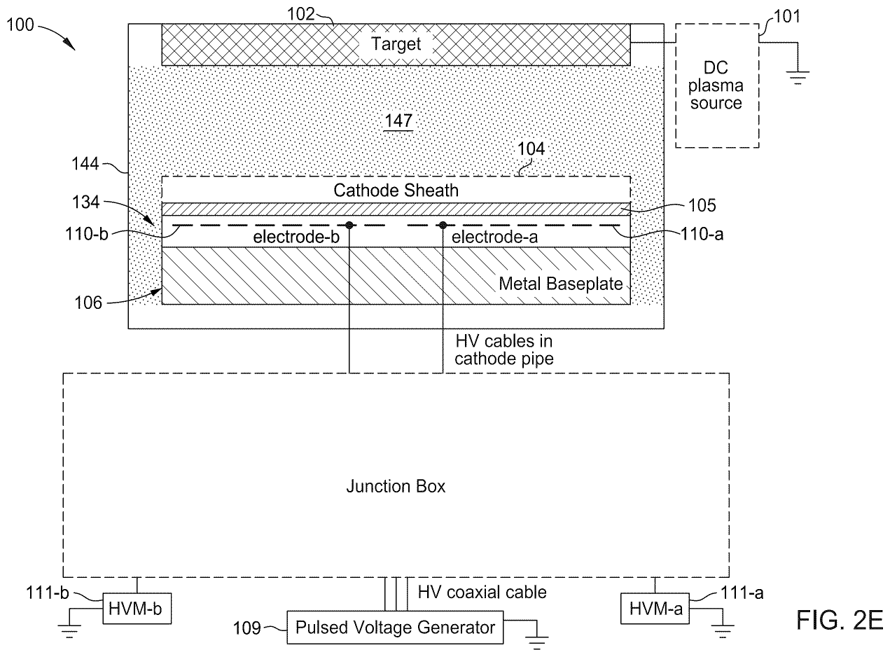

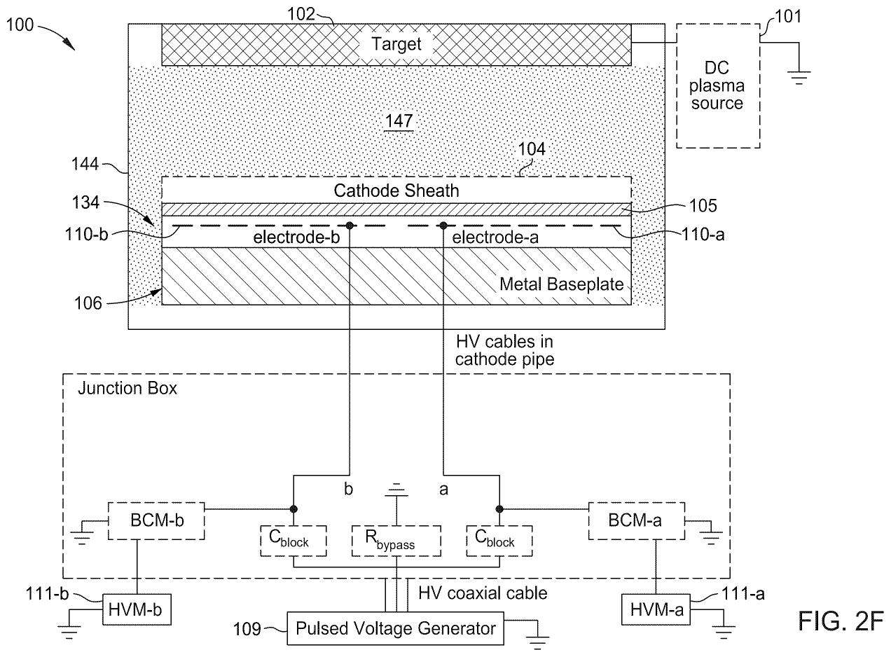

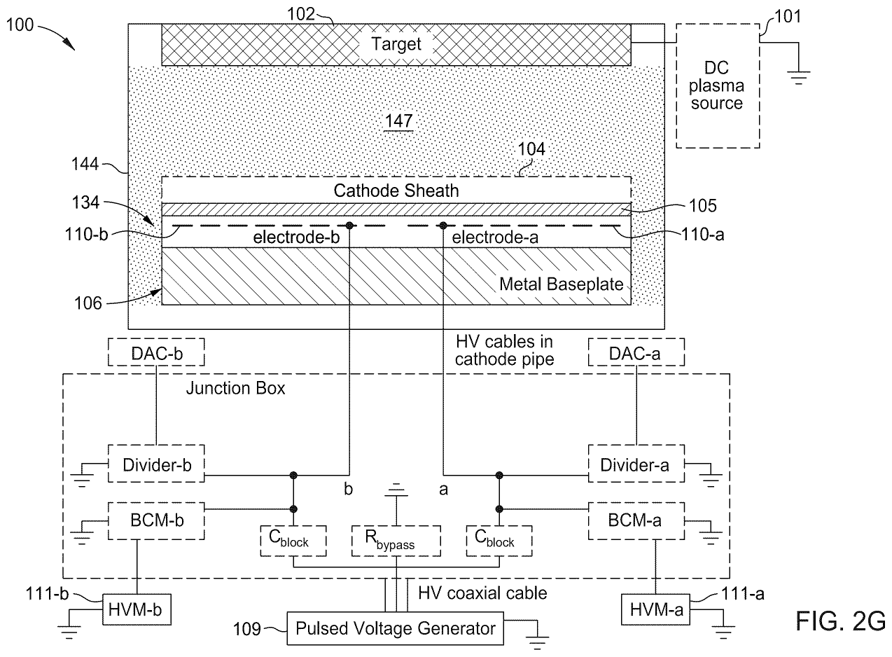

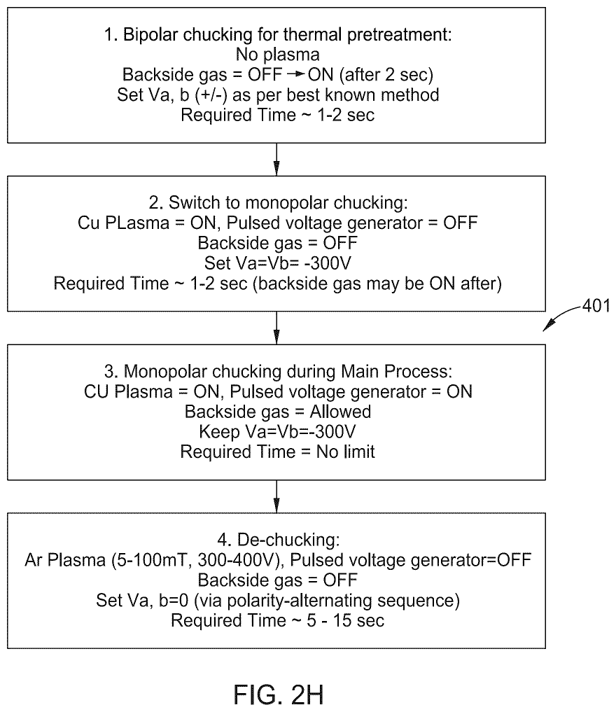

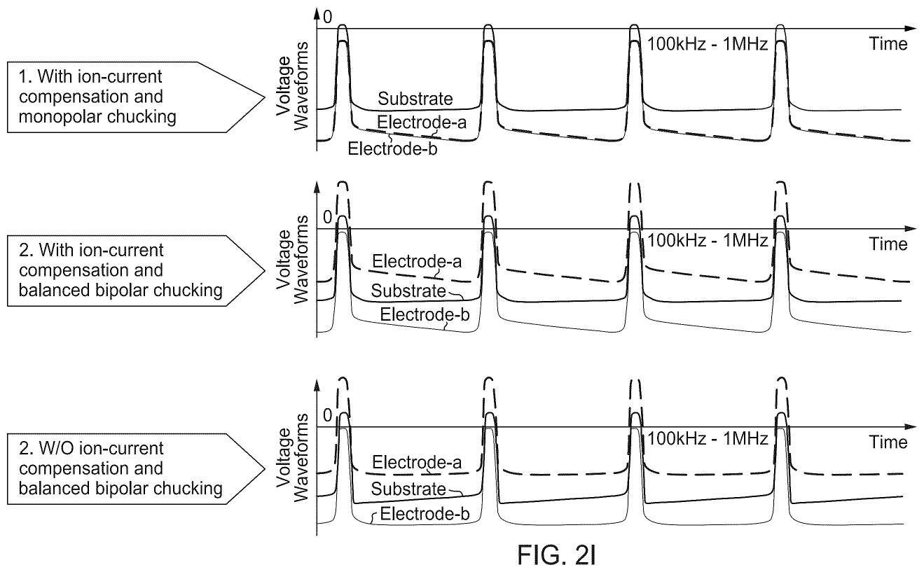

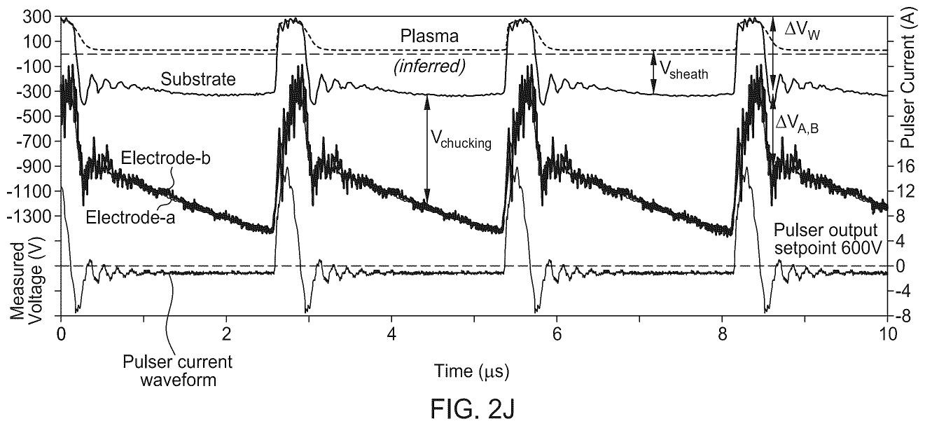

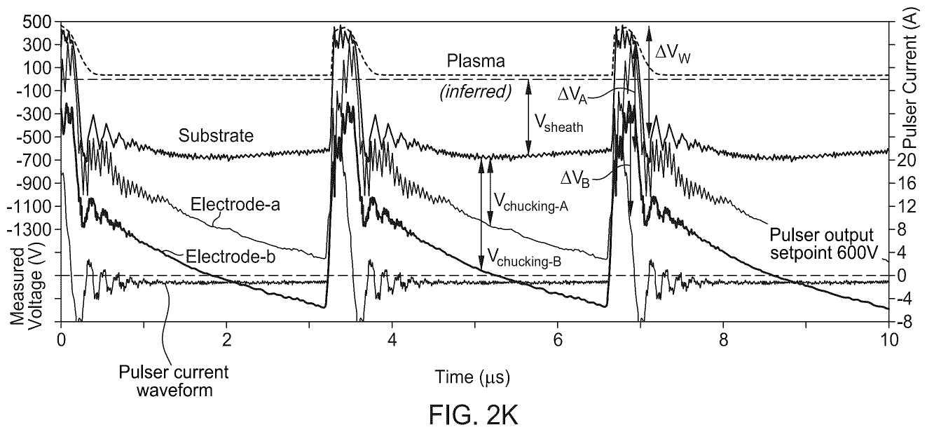

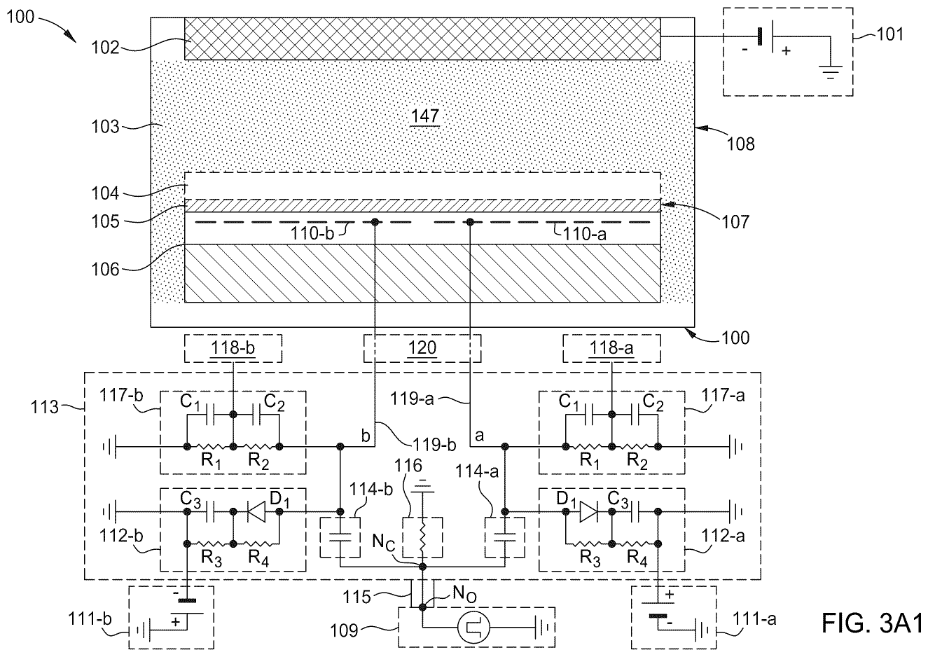

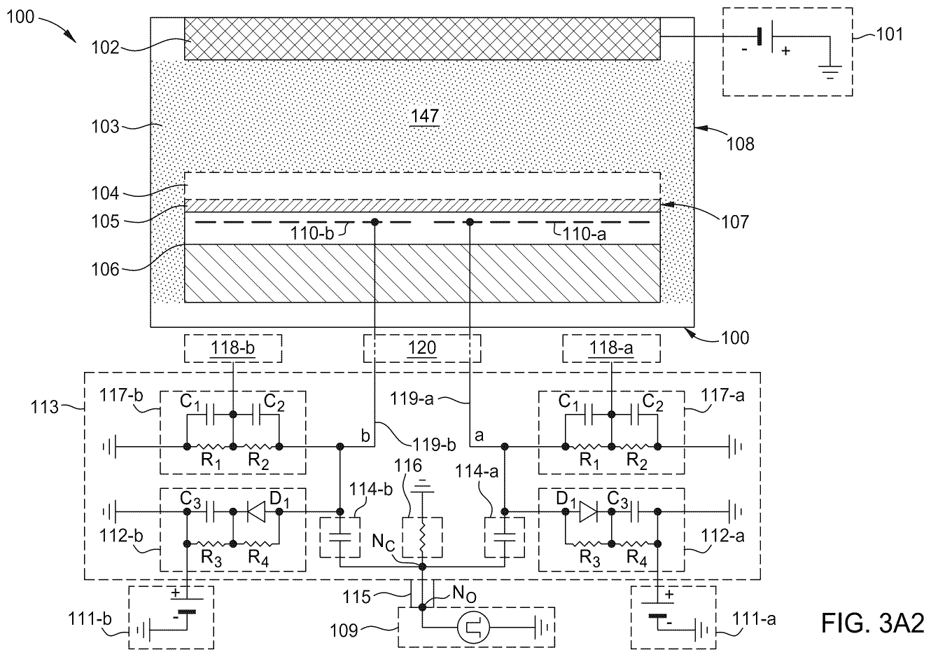

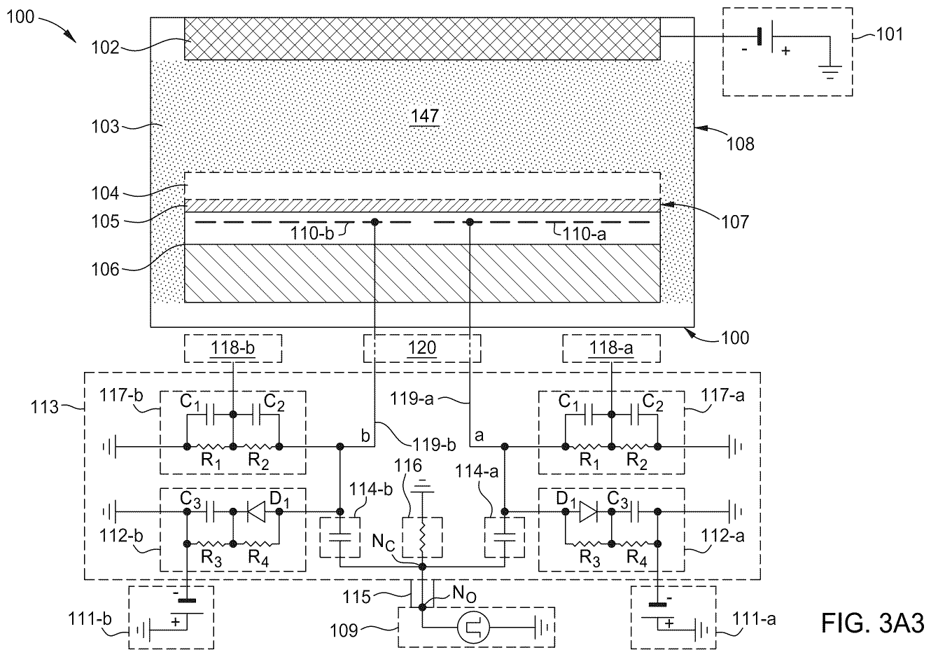

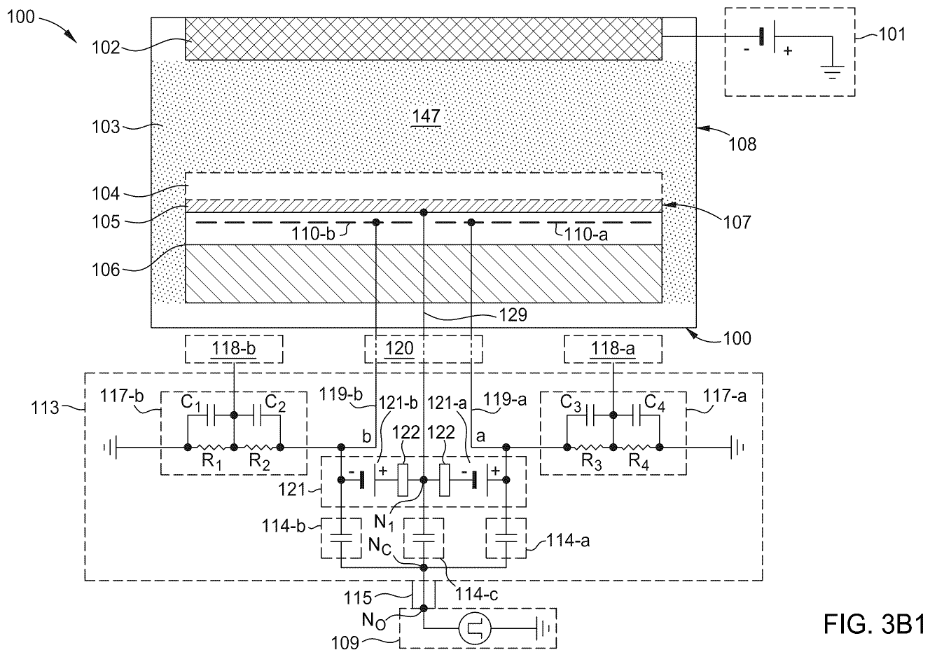

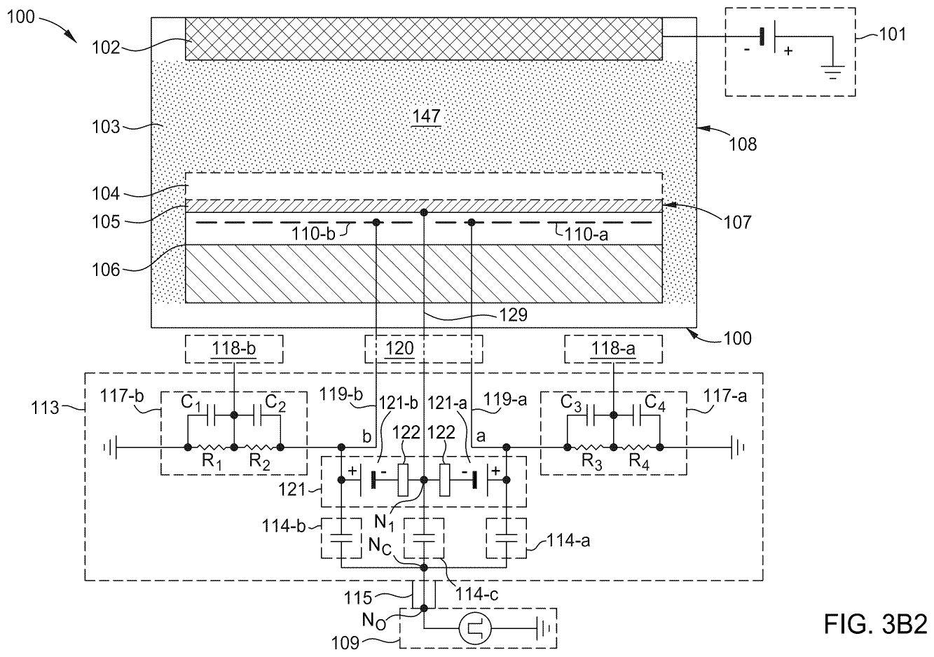

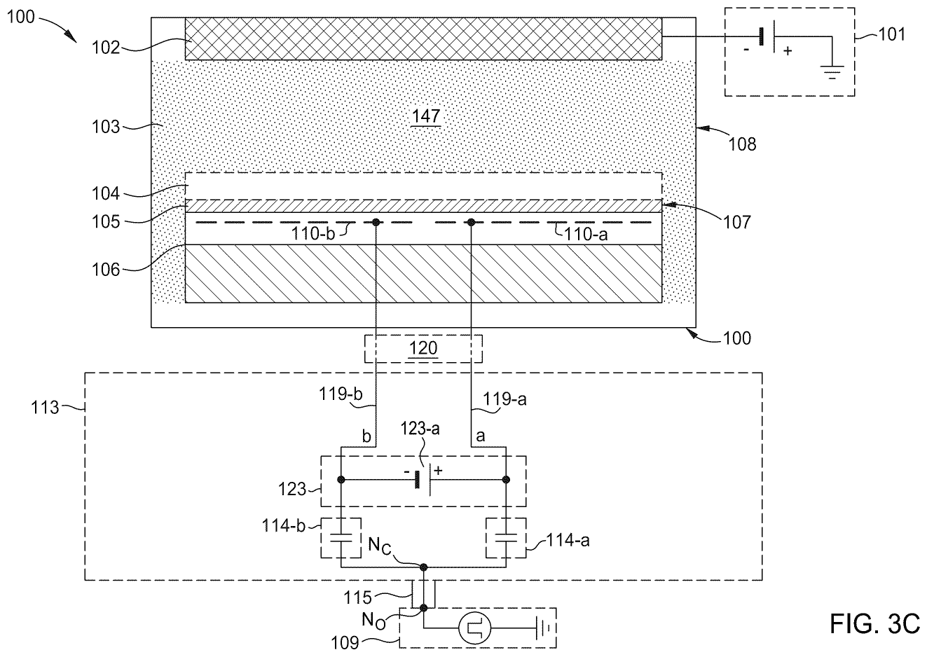

The substrate support 134 may be comprised of aluminum or ceramic. The substrate support 134 has a substrate receiving surface 138 that receives and supports the substrate 105 during processing, the substrate receiving surface 138 being substantially parallel to a sputtering surface 102A of the sputtering target 102. The substrate support 134 may be an electrostatic chuck. In some embodiments, the substrate support 134 is an electrostatic chuck that includes a dielectric body having one or more biasing electrodes 110, embedded therein. For example, as described further below in relation to FIGS. 2D-2G, 3A1-3A3, 3B1-3B2, and 3C, the substrate support 134 can include a first biasing electrode 110-a and a second biasing electrode 110-b. The dielectric body is typically fabricated from a high thermal conductivity dielectric material such as pyrolytic boron nitride, aluminum nitride, silicon nitride, alumina or an equivalent material. Other aspects of the substrate-support assembly 106 and substrate support 134 are further described below. In one embodiment, the one or more biasing electrodes 110 is configured so that when a DC voltage is applied to the one or more biasing electrodes 110, a substrate 105 disposed on the substrate receiving surface 138 will be electrostatically chucked thereto to improve the heat transfer between the substrate 105 and the substrate support 134. In some embodiments, a pulsed-voltage (PV) generator 109 is electrically coupled to the biasing electrodes 110-a and 110-b, and is configured to generate a pulsed-voltage signal that comprises a PV waveform so that a pulsed voltage signal can be provided to the substrate 105 during processing to affect and control the plasma interaction with the surface of the substrate 105. The PV generator 109 will include one or more electrical components, such as high repetition rate switches, capacitors (not shown), inductors (not shown), fly back diodes (not shown), power transistors (not shown) and/or resistors (not shown), that are configured to provide a PV waveform to an output node that is coupled to one or more biasing electrodes 110.

The substrate support 134 may be coupled to two or more high voltage DC supplies 111 that supplies a chucking voltage thereto. The high voltage DC supplies 111 may be referenced to ground or the substrate (using a so-called “center-tap”) and may be coupled to one or more biasing electrodes 110. In one configuration, a static DC voltage is between about −5000V and about +5000V, and is delivered to the electrode from the high voltage DC supplies 111 to electrostatically “chuck” a substrate 105 to the substrate receiving surface 138 of the substrate support 134 during plasma processing.

A program (or computer instructions) readable by a system controller 126 determines which tasks are performable on a substrate. In some embodiments, the system controller 126 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The system controller 126 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

Preferably, the program is software readable by the system controller 126 that includes code to perform tasks relating to monitoring, execution, and control of the movement and various process recipe tasks and recipe steps being performed in the processing chamber 100. For example, the program can comprise program code that includes a substrate positioning instruction set to operate the substrate-support assembly 106; a gas flow control instruction set to operate gas flow control valves to set a flow of sputtering gas to the processing chamber 100; a gas pressure control instruction set to operate a throttle valve or gate valve to maintain a pressure in the processing chamber 100; a temperature control instruction set to control a temperature control system (not shown) in the substrate-support assembly 106 or sidewalls 148 to set temperatures of the substrate 105 or sidewalls 148, respectively; and a process monitoring instruction set to monitor the process in the processing chamber 100. In one example, the program can comprise program code that includes an instruction set that is configured to control the delivery of voltage waveforms and the application of one or more biasing voltages to the biasing electrodes disposed within the substrate-support assembly 106.

The upper process assembly 142 may also comprise an RF source 158, a direct current (DC) source 101, an adaptor 152, a motor 154, and a lid assembly 156. The lid assembly 156 generally comprises the sputtering target 102, and a magnetron system 155. The upper process assembly 142 is supported by the sidewalls 148 when in a closed position, as shown in FIG. 1. A ceramic target isolator 160 is disposed between the isolator ring assembly 145, the sputtering target 102, and the adaptor 152 of the lid assembly 156 to prevent vacuum leakage there between. The adaptor 152 is coupled to the sidewalls 148 using a vacuum seal, and is configured to help with the removal of the upper process assembly 142 and isolator ring assembly 145.

When in the processing position, the sputtering target 102 is disposed adjacent to the adaptor 152, and is exposed to the processing region 147 of the processing chamber 100. The sputtering target 102 contains material that is deposited on the substrate 105 during a PVD, or sputtering, process. The isolator ring assembly 145 is disposed between the sputtering target 102 and the shield 141 and the chamber body 144 electrically isolating the sputtering target 102 from the shield 141 and chamber body 144.

During processing, the sputtering target 102 is biased relative to a grounded region of the processing chamber 100 (e.g., the chamber body 144 and the adaptor 152) by a power source disposed in the RF source 158 and/or the direct current (DC) source 101. It is believed that by delivering RF energy and/or DC power to the sputtering target 102 during a high pressure PVD process, significant process advantages can be achieved over conventional low pressure DC plasma processing techniques when used in conjunction with sputtering materials such as titanium, copper, nickel, ruthenium, aluminum, tantalum, molybdenum, tungsten, and other materials. In one or more examples, a DC power supply included in the DC source 101 is capable of delivering between about 0.1 and about 50 kW of DC power.

During processing, a gas, such as argon, is supplied to the processing region 147 from a gas source 162 via conduits 164. The gas source 162 may comprise an inert gas such as argon, krypton, helium or xenon, which is capable of energetically impinging upon and sputtering material from the sputtering target 102 and/or surface of the substrate 105 based on a bias applied which may be applied by the PV generator 109. The gas source 162 may also include a reactive gas, such as one or more of an oxygen-containing gas or a nitrogen-containing gas, which is capable of reacting with the sputtering material to form a layer on a substrate. Spent process gas and byproducts are exhausted from the processing chamber 100 through exhaust ports 166 that receive spent process gas and direct the spent process gas to an exhaust conduit having an adjustable position gate valve (not shown) to control the pressure in the processing region 147 in the processing chamber 100. The exhaust conduit is connected to one or more exhaust pumps 168, such as a cryopump or turbopump. Typically, the pressure of the sputtering gas in the processing chamber 100 during processing is set to sub-atmospheric levels, such as a vacuum environment, for example, a pressure of about 0.6 mTorr to about 300 mTorr during processing. In some embodiments, the processing pressure is set to about 20 mTorr to about 100 mTorr.

In some embodiments, a first electromagnet assembly 170 comprises a first current source 170A configured to bias a first magnetic coil assembly 170B. The first magnetic coil assembly 170B is positioned near the sputtering target 102, configured to modulate an upper region of the formed plasma 172. A second electromagnet assembly 174 comprises a second current source 174A configured to bias a second magnetic coil assembly 174B. The second magnetic coil assembly 174B is positioned in the central part of the chamber and configured to modulate a central portion of the plasma 172. The plasma 172 is formed between the substrate 105 and the sputtering target 102 from the gas. A portion of ions within the plasma 172 are accelerated toward the sputtering target 102 and cause material to become dislodged from the sputtering target 102. The dislodged target material is deposited on the substrate 105.

A lid enclosure 178 generally comprises a conductive wall 180, a center feed 182, and shielding (not shown). In this configuration, the conductive wall 180, the center feed 182, the sputtering target 102, and a portion of the motor 154 enclose and form a back region 184. The back region 184 is a sealed region disposed on the backside of the sputtering target 102 and is generally filled with a flowing liquid during processing to remove the heat generated at the sputtering target 102 during processing. In some embodiments, the conductive wall 180 and the center feed 182 are configured to support the motor 154 and magnetron system 155, so that the motor 154 can rotate the magnetron system 155 during processing. In one or more embodiments, the motor 154 is electrically isolated from the RF or DC power delivered from the power supplies by use of a dielectric layer, such as Delrin, G10, or Ardel. The shielding (not shown) may comprise one or more dielectric materials that are positioned to enclose and prevent the RF energy delivered to the sputtering target 102 from interfering with and affecting other processing chambers. In some embodiments, the shielding may comprise a Delrin, G10, Ardel or other similar material and/or a thin-grounded sheet metal RF shield.

To provide efficient sputtering, a magnetron system 155 is positioned behind the sputtering target 102 in the upper process assembly 142 to create a magnetic field in the processing region 147 adjacent the sputtering surface 102A of the sputtering target 102, which generates the magnetron-controlled plasma 172. A magnetic field generated by the magnetron system 155 traps electrons and ions to increase the plasma density over one or more regions of the sputtering target 102, and to increase target utilization, control deposition uniformity and the sputtering rate. In some embodiments, the magnetron system 155 includes a source magnetron assembly (not shown) that comprises an outer pole (not shown) and an inner pole (not shown). The magnetron system 158 is rotated about a central axis of the processing chamber 100 by use of the motor 154.

As will be discussed further below, to generate ion energies in the desired range, the one or more processors of the system controller 126 execute instructions that issue setpoints to the PV generator 109, thus controlling the voltage waveforms established at the biasing electrodes and the substrate. In one example, the one or more processors adjust the voltage pulse amplitudes created within the PV generator 109.

### Pulsed Voltage Substrate Biasing and Substrate Chucking Hardware and Processing Methods

A plasma generated during processing that contains a nearly mono-energetic IEDF with a predetermined single-peak energy Ep provides benefits for metal deposition process applications, including: lack of low energy ions, resulting in a narrow ion velocity angular distribution, thus limiting deposition on the side walls (“necking”, “overhang”) of features formed in a surface of the substrate; lack of ions with energies higher than Ep, which helps protect the deposition layer formed on the bottom of the features from unintended damage during a deposition step; and increasing high energy ions portion of the ion flux to the substrate for a given source power (unlike RF-bias that produces many low-mid-energy ions for a given bias power/high-energy peak). FIG. 2A illustrates an example of a desirable monoenergetic IEDF curve for a generated plasma.

A pulsed voltage waveform applied to the biasing electrodes (e.g., electrodes 110-a and 110-b) produces a substrate-voltage waveform with a nearly constant sheath voltage (potential difference b/n plasma and substrate) for a sizable portion of the pulse period, resulting in a desired narrow, single-peak IEDF. Embodiments of the disclosure provided herein include a biasing scheme for a bi-polar electrostatic chuck (ESC) that combines pulsed voltage waveform(s) with a DC voltage offset for substrate chucking. FIG. 2B illustrates a plot of a pulsed voltage waveform generated at a first bipolar ESC electrode (electrode 110-a) within an ESC, a pulsed voltage waveform generated at a second bipolar ESC electrode (electrode 110-b) within the ESC, and a pulsed voltage waveform established on a substrate positioned on a surface of the ESC by use of a PV source during processing. Unless specifically stated otherwise herein, the voltage at any physical point within the processing chamber is defined as potential relative to ground.

Referring to FIG. 2C, during metal deposition, metal ions sputtered from a metal target are accelerated towards the substrate by a voltage drop in an electron-repelling sheath formed over it. A substrate is placed on top of electrostatic chuck (ESC). A cylindrical metal wall of the processing chamber provides a current-return grounded surface for bias and source (DC voltage applied to a target).

Referring to FIG. 2D, an ion-accelerating cathode sheath is formed by using a pulsed voltage generator to produce a pulsed-voltage waveform at biasing electrodes, such as chucking electrodes that are embedded into the electrostatic chuck (ESC) and are separated from the substrate by a thin layer of dielectric material. Due to higher capacitance (thinner ceramic layer) between the ESC electrodes and substrate compared to that for RF baseplate, biasing at the electrodes results in following advantages: (1) smaller voltage ramp must be produced by pulsed voltage generator for ion-current compensation (or smaller substrate voltage droop and narrower IEDF if not ramping); and (2) larger portion of negative voltage jump at the beginning of the pulse (determining sheath voltage drop) occurring across the sheath, due to smaller Cₛₕ/C_{esc} voltage split. The term “voltage droop”, as used herein, refers to the slope (typically upward, indicating sheath voltage magnitude reduction) in the substrate voltage waveform during ion-current phase, and the term “voltage ramp” (typically downward, allowing sheath voltage to remain nearly constant) relating to “ion-current compensation” or “bias compensation” refers to the slope in the electrode voltage waveform during the same time interval.

Referring to FIG. 2E, during plasma processing, the temperature of the substrate is controlled by chucking the substrate to a surface of a pixelated (e.g., multi-electrode) ESC and filling the several-micron-tall gap with an amount (e.g., a few Torr) of backside cooling gas (Ar) to improve thermal conductivity. To achieve stable electrostatic chucking, voltage waveforms at biasing electrodes need to be offset from substrate voltage waveform by one (“monopolar” chucking) or more (“bipolar” chucking) voltage values: (1) +/−100V-+/−300V for Johnson-Rahbeck chuck (JR-ESC) used here; (2) +/−1000V-+/−4000V for Coulombic chuck (C-ESC) used in many plasma processing chambers (e.g., Etch chambers). Voltage offsets are produced by high-voltage modules (HVM-a,b) that will include HVDC power supplies (e.g., DC voltage supplies 111-a, 111-b).

Referring to FIG. 2F, two HVDC voltage supplies (HVM) are coupled to biasing electrodes through two bias compensation modules (BCM) housed in a junction box (Jbox) to enable reliable substrate chucking and protect HVMs from the pulsed voltage provided by the pulsed voltage generator 109. Two blocking capacitors (e.g., C_{block}=22 nF) are disposed in series with a coaxial cable coupling the pulsed voltage generator to Jbox—to protect it from DC voltages produced by HVMs. Bypass resistor (e.g., R_{bypass}=1MΩ) coupling a center conductor of the coaxial cable to ground to charge and discharge blocking capacitors in the absence of the PV generator 109.

Referring to FIG. 2G, to monitor and control voltage waveforms at the biasing electrodes, including voltage offsets to substrate waveform (“chucking voltages”) during plasma processing, two resistive-capacitive voltage dividers in J-box (e.g., between center conductors of cables to biasing electrodes and ground (GND)) are used to output waveforms to one or more data acquisition systems (e.g., DAC-a and DAC-b). Controlling voltage offsets helps achieving balanced bipolar-chucking operation during all of the process recipe steps: (1) pre-plasma: substrate can be chucked before igniting the plasma (for thermal pre-treatment); (2) plasma: voltage offsets for two electrodes have opposite signs and remain near same absolute values; and (3) post-plasma: total substrate charge that may accumulate in plasma is small and dechucking may be performed without plasma, thus eliminating a possibility for uncontrolled metal deposition.

FIG. 2H illustrates a metal deposition plasma processing sequence that includes: (1) a bipolar chucking for thermal pretreatment step (no plasma) that includes turning “on” the backside gas after the substrate has been chucked for a first period of time (e.g., after 2 seconds) and the chucking voltages Va, Vb are set to a desired positive and a desired negative voltage, respectively, that are each applied to a bipolar ESC electrode (110-a and 110-b); (2) switching to a monopolar chucking step that includes generating a plasma within the processing chamber, while the PV source is “off”, the backside gas is turned “off”, and the chucking voltages Va, Vb applied to the bipolar ESC electrodes (110-a and 110-b) are both set to first negative voltage (e.g., −300 Vdc) for a second period of time (e.g., 1-2 seconds); (3) monopolar chucking during main plasma processing step which includes maintaining a plasma within the processing chamber, while the PV source is “on”, the backside gas is turned “on” or “off”, and the chucking voltages Va, Vb applied to the bipolar ESC electrodes (110-a and 110-b) are both set to a second negative voltage (e.g., −300 Vdc) for a desired period of time; and then performing (4) a de-chucking step that includes turning off the DC source generating the plasma (e.g., target power source) within the processing chamber, maintaining a chamber pressure of between 5-100 mTorr, turning the backside gas “off”, the PV source “off”, and setting the chucking voltages Va, Vb applied to the bipolar ESC electrodes (110-a and 110-b) to zero using the polarity alternating sequence for a desired period of time (e.g. 5-15 seconds). The process of maintaining the chamber pressure during the de-chucking step is desirable, since it not only provides plasma charges to complete the current path needed for charge-removal and dechucking, but also scatters sputtered atoms (e.g., Cu) atoms and ions from the target, thus preventing them from reaching and depositing on the ESC top surface when the substrate gets lifted at the end of the dechucking step. Such deposition on ESC surface would result in average plasma-side charge residing at the bottom of the deposited metal layer, instead of the bottom of the substrate, resulting in a near-zero net substrate-clamping force. FIG. 2I illustrates voltage waveforms that may be applied to bipolar electrodes within an electrostatic chuck (ESC) within a plasma processing chamber by a pulse voltage (PV) source. In a first example, PV waveforms that include ion-current compensation and monopolar chucking is illustrated in the top-most plotted waveform curves. In a second example, PV waveforms that include ion-current compensation and a balanced bipolar chucking is illustrated in the middle plotted waveform curves. In a third example, PV waveforms that do not include ion-current compensation, but include balanced bipolar chucking, are illustrated in the bottom-most plotted waveform curves.

FIG. 2J illustrates voltage waveforms that were measured using Pico-scope, simultaneously at four locations: wired-substrate (low resistivity Si), biasing (chucking) electrodes A, B (via dividers and HV-probe), pulser output; pulser current was measured using a current transducer. Data shows that negative voltage jumps at the electrodes, ΔVA, B, and at the substrate (e.g., wafer ΔV_{w}), are close to the pulser output setpoint, but the sheath voltage, Vₛₕₑₐₜₕ=Vₚₗₐₛₘₐ−V_{substrate(wafer)} is reduced by the plasma potential jump. The substrate and sheath voltages were successfully maintained at a nearly constant level throughout the pulse by applying a voltage ramp to the pulser output and electrodes voltages, producing a nearly mono-energetic IEDF. Chucking voltage between the substrate and electrodes was maintained at levels sufficient for stable substrate clamping during recipe.

FIG. 2K illustrates negative voltage jumps at electrodes, ΔV_{A, B}, and at the substrate, ΔV_{W}, are again close to the pulser output setpoint. The substrate and sheath voltages were again maintained at nearly constant levels during the provided pulse and increased due to higher PVT voltage. Chucking voltages were unbalanced for A, B-electrodes (total substrate charge≠0), even for opposite HVM voltage setpoints, due to plasma potential jump and ion-current compensating voltage ramp. For electrode A, average chucking voltage V_{chucking}=V_{electrode}−V_{Substrate(wafer)} was negative despite positive HVM setpoint (due to above). One will note that due to charge trapping near top surface in JR-ESC, chucking voltage varies weakly from its average value during pulse period.

In conclusion, nearly mono-energetic IEDF with a given single-peak energy provides benefits for metal deposition applications. A pulsed voltage waveform at biasing electrodes produces a substrate-voltage waveform with a nearly constant sheath voltage (potential difference b/n plasma and substrate) for a sizable portion of the pulse period, resulting in a desired narrow, single-peak IEDF. Embodiments of the disclosure include a biasing scheme for a bipolar ESC that combines a pulsed voltage waveform with a DC voltage offset for substrate chucking. Both bipolar and monopolar chucking have been developed with a variety of pulsed waveforms. The processes disclosed herein were able to provide substrate and sheath voltages that were successfully maintained at nearly constant levels throughout the pulse by applying a voltage ramp to the pulser output and electrode voltages, producing a nearly mono-energetic IEDF. Likewise, the chucking voltage between the substrate and the electrodes was maintained at levels sufficient for stable substrate clamping throughout the delivery of the pulses.

### Metal Deposition Using Pulsed Voltage Techniques

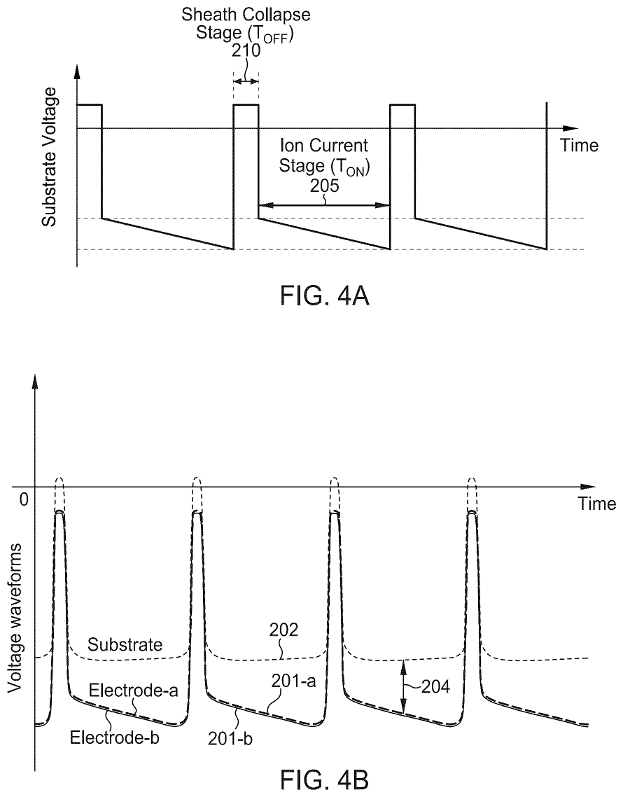

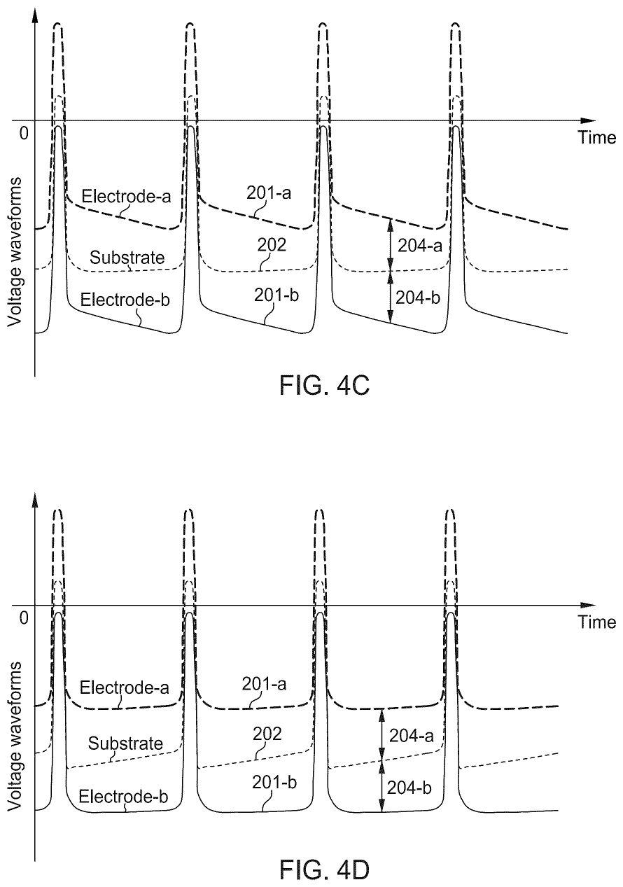

Referring to FIG. 3A1-3C, in the processing chamber 100, the plasma is created by applying a pulsed voltage waveform from the DC source 101 to the target 102, which supplies both high-energy secondary electrons and metal atoms into the discharge volume, or also referred to as the process region 147. The pressure in the process region 147 during plasma processing is typically in the sub-mTorr range, allowing metal ions to reach the deposition substrate with few ion-neutral collisions and mostly vertical velocity. FIG. 3A1 illustrates a cross-sectional view of an example of a processing chamber that includes a first bipolar electrostatic chuck configuration. FIG. 3A2 illustrates a cross-sectional view of a first example of a processing chamber that includes a first monopolar electrostatic chuck configuration. FIG. 3A3 illustrates a cross-sectional view of a second example of a processing chamber that includes a second monopolar electrostatic chuck configuration. FIG. 3B1 illustrates a cross-sectional view of an example of a processing chamber that includes a second bipolar electrostatic chuck configuration. FIG. 3B2 illustrates a cross-sectional view of an example of a processing chamber that includes a third monopolar electrostatic chuck configuration. FIG. 4A illustrates a voltage waveform that may be applied to an electrode in the processing chamber by a pulse voltage (PV) source. FIG. 4B illustrates a voltage waveform that is established on a substrate due to voltage waveforms applied to a first electrode 110-a and a second electrode 110-b disposed within a substrate support of the processing chamber.

During a metal deposition process, ions of a target-sputtered material (e.g., Cu) are accelerated towards the substrate by the voltage drop in an electron-repelling sheath 104 that forms over the substrate 105 placed on top of a substrate-support assembly 106. The substrate-support assembly 106 comprises an electrostatic chuck (ESC) assembly 107 and may be referred to as a “cathode assembly” or a “cathode”.

A cylindrical metal wall 108 provides a grounded surface for bias and source return-currents. The wall may be up to 1 m tall to produce a sufficiently large distance between the target on the top and the substrate at the bottom. This distance comprises several electron-neutral collisional mean free paths and provides for efficient ionization of metal atoms by energetic secondary electrons.

An ion-accelerating cathode sheath 104 may be formed by use of a pulsed voltage generator 109 (or PV source 109) to establish a pulsed-voltage waveform 201 at one or more biasing electrodes, such as chucking electrodes (e.g., electrodes 110-a, 110-b), that are disposed within the electrostatic chuck (ESC) assembly and are separated from the substrate by a thin layer of a dielectric material.

This pulsed voltage waveform results in a substrate-voltage waveform 202 (FIG. 4B) characterized by a nearly constant sheath voltage (a difference between the plasma potential and the substrate potential) for a sizable portion of the pulse period, which corresponds to a single (narrow) peak ion energy distribution function (FIG. 2A), or ion energy distribution function (IEDF), of the ions reaching the substrate during this time interval (which may be referred to as the “ion-current phase”).

Such nearly mono-energetic IEDF with a predetermined single-peak energy Eₚ, for example 30 eV−3000 eV, can have multiple benefits for metal deposition process applications, including: (1) lack of low energy ions, resulting in a narrow ion velocity angular distribution that helps limit deposition on the side walls at the top of the feature formed in a surface of the substrate or at the feature formed in the mask (so called “necking”); (2) lack of ions with energies higher than Eₚ, which helps protect the deposition layer at the bottom the formed feature due to unintended sputtering.

During plasma processing, the temperature of the substrate is typically controlled by electrostatically chucking (clamping) the substrate to the top surface of the electrostatic chuck assembly, whose temperature is in turn controlled by embedded liquid cooling and/or electric heating elements. The gap between the substate and the surface of the ESC (e.g. few to several microns tall) can then be filled with a backside cooling gas (e.g., Ar or He) at a pressure of between a few and few tens of Torrs to improve thermal conductivity. To provide a stable electrostatic chucking, biasing electrodes voltage waveforms need to be offset from substrate voltage waveform by one (for “monopolar” chucking) or more (for “multipolar” chucking) voltage values, for example, +/−100V-+/−300V for Johnson-Rabeck chuck (JR-ESC), or +/−1000V-+/−4000V for Coulombic chuck (C-ESC).

In one processing chamber example, as shown in FIG. 3A1, a stable electrostatic chucking technique can be accomplished by employing a combination of: (1) one or more chucking modules, comprising direct-current voltage supplies 111 coupled to biasing electrodes through bias compensation modules 112 housed within a junction box 113; (2) the use of blocking capacitors 114, (e.g., 1 nF-100 nF capacitor), disposed in series with a first transmission line 115 (e.g., coaxial cable), (3) coupling the pulsed voltage generator 109 to the junction box 113; and (4) the use of a bypass resistor 116 (e.g., 0.4MΩ-4MΩ resistor), coupled between the electrical conductor of the transmission line 115 and the ground. As shown in FIG. 3A1, the bias compensation modules (BCM) 112, which include passive electrical elements, such as a capacitor C3, a diode D1, and resistors R3 and R4, are coupled between ground and the electrical conductors 119-a and 119-b at a point between the blocking capacitors 114a, 114-b and the biasing electrodes 110-a, 110-b. In one example, the electrical conductors 119-a and 119-b include center conductors of a coaxial cable. The transmission line 115 connects a PV generator output coupling assembly, which is positioned at the output of the PV generator 109 (i.e., node N_{O}), to the circuit elements (e.g., bias compensation modules 112, blocking capacitors 114, electrical conductors 119-a and 119-b, etc.) positioned in the junction box 113. The PV generator 109 and PV generator output coupling assembly are coupled to the output of the PV generator 109 that is connected to the output node N_{O}. The transmission line 115 electrically connects the output node N_{O} to a connection point at node N_{C} and the circuit elements, which can all be located in the junction box 113.

To monitor and control the generated voltage waveforms 201 at the biasing electrodes 110-a, 110-b, one or more resistive-capacitive voltage dividers 117 may be employed to provide information (e.g., electrical signal(s)) relating to the output voltage waveforms to one or more data acquisition systems 118 and system controller 126. The generated voltage waveform will include a voltage offset 204 (FIG. 4B) relative to the substrate voltage waveform, created by the application of the “chucking voltage”, during plasma processing. The system controller 126 can use the electrical signals received from the data acquisition systems 118-a, 118-b to set, adjust, and/or control the pulsed voltage waveform shape over time that is provided from the PV generator 109 and/or the chucking voltages supplied by the DC voltage supplies 111-a, 111-b to the electrodes 110-a, 110-b during processing.

In some embodiments, the voltage dividers 117 may be housed within the junction box 113 and disposed between electrical conductors 119 of a second transmission line 120 coupling the junction box 113 to biasing electrodes 110, and ground. As shown in FIG. 3A1-3B2, the voltage dividers 117-a, 117-b, which include capacitors C1 and C2 and resistors R1 and R2, are coupled between ground and the electrical conductors 119-a and 119-b, respectively. Controlling voltage offsets helps achieving a balanced bipolar-chucking operation, in which: (1) voltage offsets for two biasing electrodes 110-a, 110-b have opposite signs and remain near the same absolute value throughout the processing recipe; (2) substrate can be chucked before igniting the plasma for thermal pre-treatment; (3) total substrate charge that may accumulate during plasma processing is small and dechucking may be accomplished without the formed plasma, thus eliminating a possibility for uncontrolled metal deposition.

FIG. 3B1 and 3B2 illustrate alternate configurations of the processing chamber 100 that include a differently configured biasing circuit positioned within the junction box 113. The biasing circuit includes a floating bipolar direct-current voltage supply 121. The biasing circuit can optionally include a center tap 129, which, when present, is connected to the node N₁ and is in communication with the substrate supporting surface of the ESC. In this processing chamber example, a stable electrostatic chucking technique can be accomplished by employing a combination of: (1) the floating bipolar direct-current voltage supply 121; (2) the use of blocking capacitors 114-a, 114-b, and 114-c that are disposed in series with a first transmission line 115 and each electrical conductor 119-a, 119-b, and (3) coupling the pulsed voltage generator 109 to the transmission line 115. The floating bipolar direct-current voltage supply 121 will include a first DC power supply 121-a connected between the node N₁ and the electrical conductor 119-a, and a second DC power supply 121-b connected between the node N₁ and the electrical conductor 119-b. In some embodiments, the floating bipolar direct-current voltage supply 121 is configured to generate an opposite DC bias on the electrical conductors 119-a, 119-b. In one example, as shown in FIG. 3B1, the first DC power supply 121-a is configured to positively bias the electrical conductor 119-a relative to the node N₁, and the second DC power supply 121-b is configured to negatively bias the electrical conductor 119-b relative to the node N₁. Alternately, in another example, as shown in FIG. 3B2, the first DC power supply 121-a is configured to positively bias the electrical conductor 119-a relative to the node N₁, and the second DC power supply 121-b is configured to positively bias the electrical conductor 119-b relative to the node N₁. In some embodiments, a filter 122 is positioned in series with each of the DC power supplies 121-a and 121-b between the node N₁ and their respective electrical conductor 119-a, 119-b, as shown in FIG. 3B1-3B2, to protect the DC power supplies during processing. The filters 122 can include filtering elements that include resistive, inductive, and capacitive components. In one example, the filters 122 can include LC circuit topologies, such as Pi or Tee networks.

The system controller 126 can use the electrical signals received from the data acquisition systems 118-a, 118-b to set, adjust, and/or control the pulsed voltage waveform shape over time that is provided from the PV generator 109 and/or the amount of DC bias applied by the DC power supplies 121-a, 121-b to the electrical conductors 119-a, 119-b, respectively, relative to the node N₁. Controlling voltage offsets and PV waveform shape will help to achieve desirable process results using a balanced bipolar-chucking process.

FIG. 3C illustrates another alternate configuration of the processing chamber 100 that includes a differently configured biasing circuit positioned within the junction box 113. The biasing circuit includes a floating direct-current voltage supply 123, which can optionally include a center tap 129 (not shown). In this processing chamber example, a stable electrostatic chucking technique can be accomplished by employing a combination of: (1) the floating direct-current voltage supply 123; (2) the use of blocking capacitors 114-a and 114-b that are disposed in series with a first transmission line 115 and each electrical conductor 119-a, 119-b; and (3) coupling the pulsed voltage generator 109 to the transmission line 115. The floating direct-current voltage supply 123 will include a single DC power supply 123-a connected between the electrical conductor 119-a and the electrical conductor 119-b. The floating direct-current voltage supply 123 is configured to generate an opposing DC bias on the electrical conductors 119-a and 119-b and thus electrodes 100-a and 110-b. In one example, as shown in FIG. 3C, the single DC power supply 123-a is configured to positively bias the electrical conductor 119-a relative to the electrical conductor 119-b.

### Pulsed-Voltage Waveform Examples

FIG. 4A illustrates a voltage waveform that may be established at an electrode of a processing chamber, such as one or more biasing electrodes 110, by the delivery of a compensated voltage waveform, which includes a plurality of PV pulses, to an output node of the pulsed voltage generator 109. The PV pulses include asymmetric (i.e., non-sinusoidal) voltage pulses that have a pulsing frequency, for example, of between about 50 kHz and 1 MHz, such as between 100 kHz and 500 kHz. The voltage pulses within the voltage waveform supplied by the PV generator 109 include two stages: an ion current stage 205 and a sheath collapse stage 210, as shown. Implementing the slope in the PV waveform established at the electrode(s) during the ion current stage 205 is referred to herein as ion current compensation or simply current compensation.

As discussed briefly above, at the beginning of the ion current stage 205, a negative voltage jump produces an ion space-charge sheath 104 (FIG. 1) over the substrate, accelerating ions towards it. Positive ions reaching the surface of the substrate during the ion current stage 205 deposit a positive charge, which if left uncompensated causes the sheath voltage magnitude to gradually decrease (i.e. the sheath to collapse) and the substrate voltage (potential to ground) to become less negative (i.e. to exhibit a “voltage droop”) during the ion current stage 205, as illustrated by voltage waveform 202 in FIG. 4D. To limit the amount of voltage droop experienced during the ion current stage 205, the sheath collapse stage 210 is provided to remove or reset the charge accumulated on the surface of the substrate (and the corresponding charges at biasing electrodes), so that the substrate negative voltage jump (determining sheath voltage) can then be reapplied at a desired value at the start of the subsequent ion current stage 205 of a subsequent voltage pulse. In a steady-state pulsed-voltage operation, by the end of the sheath collapse stage 210, all ion-current related charges must be completely removed from the system (equivalent circuit) to restore voltage (potential to ground) at the generator-coupling side of the blocking capacitor 114 to its value at the beginning of the ion-current phase 205. Otherwise, the negative voltage jump at the beginning of the ion-current phase of the subsequent pulse will be reduced, since the lowest point in the voltage waveform at the output of the PV generator (coupled to the blocking capacitors 114 is internally referenced to ground.

To further limit or prevent a sheath voltage magnitude decrease and a voltage droop in the substrate voltage waveform during the ion-current stage 205, in some PV waveform delivery processes, a voltage waveform that is established at the biasing electrode(s) may have a negative slope during the ion-current stage 205, as shown in FIG. 4A and waveforms 201-a, 201b in FIG. 4B, which are applied to the electrodes 110-a, 110b, to establish a square shaped region (e.g., near zero slope) in the voltage waveform established on the substrate, as shown by voltage waveform 202 in FIG. 4B. The slopes of the waveforms 201-a and 201-b are used as a voltage offset 204 to compensate for charge accumulation on the substrate over time during the ion current phase. FIG. 4C illustrates a biasing scheme that includes a bias compensation scheme in which the electrodes 110-a, 110b are biased to different DC voltage levels during the different phases of a PV pulse within the voltage waveform. FIG. 4D illustrates a biasing scheme in which a bias is applied to the electrodes 110-a, 110b, which is uncompensated and applied at different DC voltage levels during the different phases of a PV pulse within the generated voltage waveforms. The difference in substrate voltage (determining the sheath voltage, assuming near-zero plasma potential during the ion-current stage) between the beginning and the end of the ion current stage 205 (i.e., the voltage droop illustrated by the waveform 202 in FIG. 4D) determines an ion energy distribution function (IEDF) width. The greater the voltage difference seen in the voltage waveform established on the substrate during the time between the start and end of the ion current stage, the broader the IEDF. To create a narrower IEDF, operations are performed to flatten the substrate voltage waveform during the ion current stage 205 using current compensation.

In some embodiments, a plasma processing sequence will generally include the following steps. During a first step within the plasma processing sequence, a substrate positioned on a bipolar ESC within a plasma processing chamber is chucked to a substrate supporting surface of the bipolar ESC for a first period of time (e.g., about 2 seconds), wherein the process of chucking the substrate includes applying a first chucking voltage Va to the first electrode 110-a, and applying a second chucking voltage Vb to the second electrode 110-b, while no plasma is formed within the plasma processing chamber and no voltage waveform is applied to the electrodes 110-a, 110-b. The first chucking voltage Va and the second chucking voltage Vb during the first step are set to a desired positive and a desired negative voltage, respectively. A backside gas flow may be provided between the substrate and the substrate supporting surface of the ESC during the first step. Next, during a second step, the first chucking voltage Va and the second chucking voltage Vb are both set to a first negative voltage (e.g., −300 Vdc) for a second period of time (e.g., 1-2 seconds), while no plasma is formed within the plasma processing chamber and no voltage waveform is applied to the electrodes 110-a, 110-b by the PV generator 109. The delivery of the first negative voltage to both electrodes 110-a and 110-b allows the bipolar ESC assembly 107 to initiate a monopolar ESC chucking operation. In some embodiments, a backside gas flow is not provided between the substrate and the ESC during the second step. In some embodiments, the second step is only optionally performed between the first and third steps, and thus in some cases the processing method includes proceeding from the first step directly to the third processing step. Next, during the main plasma processing step (or third processing step), which includes generating and maintaining a plasma within the plasma processing chamber, the PV generator 109 is configured to deliver a voltage waveform, such as the voltage waveform illustrated in FIG. 4B to the first electrode 110-a and the second electrode 110-b, while a second negative voltage (e.g., −300 Vdc) is provided to both bipolar ESC electrodes 110-a and 110-b for a desired period of time. The application of a second negative voltage to both bipolar ESC electrodes 110-a, 110-b is used to achieve a monopolar chucking state, which requires the plasma to be present over the substrate during this processing step. In this example, the generated plasma can be formed by DC biasing a target 102. The processing pressure during the main plasma processing step can be between 0.1 mTorr and 20 mTorr, such as less than 10 mTorr, or between 1 mTorr and 5 mTorr. After performing the main plasma processing step, a de-chucking step is performed to allow the substrate to be removed from the substrate supporting surface of the ESC. The de-chucking step includes extinguishing the plasma formed in the prior step, while maintaining a plasma processing chamber pressure at desired pressure (e.g., 5-100 mTorr, or even 10 to 100 mTorr), turning the backside gas flow “off”, halting the delivery of the voltage waveform provided from PV generator 109, and setting the chucking voltages Va, Vb applied to the bipolar ESC electrodes 110-a and 110-b to zero. The process of setting the chucking voltages Va, Vb applied to the bipolar ESC electrodes 110-a and 110-b to zero can be performed by alternating the polarity of chucking voltages Va, Vb while ramping the applied chucking voltages Va, Vb to zero over a desired period of time (e.g., 5 -15 seconds). In some other examples, during the main plasma processing step, the PV generator 109 is configured to deliver voltage waveform(s), such as the voltage waveforms 201-a, 201-b illustrated in FIG. 4C or 4D to the first electrode 110-a and the second electrode 110-b, while applying a biasing voltage between the bipolar ESC electrodes 110-a and 110-b for a desired period of time. In this example, the circuits formed within the junction box of the processing chamber 100, as illustrated in FIG. 3B1-3B2 or 3C, can be used to apply a bias voltage between the bipolar ESC electrodes 110-a and 110-b (e.g., bipolar chucking process) during the delivery of the PV waveform during plasma processing.

### Additional Method and Apparatus Examples

Embodiments of disclosure include a processing chamber assembly, comprising: a chamber comprising a substrate-support assembly; a pulsed voltage generator comprising an output connection that is electrically coupled to a plurality of biasing electrodes embedded within the substrate-support assembly; and one or more chucking modules, wherein each chucking module of the one or more chucking modules comprises a direct-current voltage supply that is electrically coupled to one of the plurality of biasing electrodes through a corresponding bias compensation module. The bias compensation module can include a plurality of passive electrical components, wherein the plurality of passive components comprises a diode, a plurality of resistors, and a capacitor, wherein the diode and the capacitor are connected in series and coupled between ground and the first point on the electrical conductor.

In some cases, each biasing electrode within the processing chamber assembly is coupled to an output of the pulsed voltage generator via an electrical conductor and a blocking capacitor. Each of the bias compensation modules and direct-current voltage supplies of the one or more chucking modules can be electrically coupled to the corresponding electrical conductor at a first point between the corresponding blocking capacitor and the corresponding biasing electrode. Additionally, the processing chamber assembly includes a bypass resistor, wherein the bypass resistor is coupled between ground and the output connection of the pulsed voltage generator. The processing chamber assembly can further include a data acquisition system coupled to the electrical conductor at a second point between the blocking capacitor and the biasing electrode of the plurality of biasing electrodes, wherein a voltage divider is electrically coupled between an input of the data acquisition system and the second point.

The one or more chucking modules of the processing chamber assembly can include: a first chucking module that comprises a first direct-current voltage supply that is electrically coupled to a first biasing electrode of the plurality of biasing electrodes through a first bias compensation module; and a second chucking module that comprises a second direct-current voltage supply that is electrically coupled to a second biasing electrode of the plurality of biasing electrodes through a second bias compensation module. The first direct-current voltage supply is configured to provide a first voltage having a first polarity to the first biasing electrode, and the second direct-current voltage supply is configured to provide a second voltage having a second polarity to the second biasing electrode, wherein the first polarity is opposite to the second polarity.

In some embodiments, the processing chamber assembly includes a direct current (DC) power source that is configured to apply a voltage to a target, wherein applying a voltage to the target is configured to generate a plasma over a substrate supporting surface of the substrate support.

Embodiments of disclosure include a plasma processing method, comprising: electrostatically chucking a substrate to a substrate supporting surface of a substrate support for a first period of time by applying a first bias voltage to a first biasing electrode and applying a second bias voltage to a second biasing electrode by use of one or more direct-current voltage supplies, wherein the first bias voltage and the second bias voltage are different, the substrate supporting surface is disposed within a processing region of a processing chamber, and the first biasing electrode and the second biasing electrode are disposed within the substrate support. Then electrostatically chucking the substrate to the substrate supporting surface for a second period of time by applying a third bias voltage to the first biasing electrode and the second biasing electrode by use of the one or more direct-current voltage supplies; and establishing a first voltage waveform at the first biasing electrode and a second voltage waveform at the second biasing electrode while the third bias voltage is applied to the first biasing electrode and the second biasing electrode. The plasma processing method can also further include offsetting the first voltage waveform and the second voltage waveform by one or more voltage values. The plasma processing method can further include dechucking the substrate after establishing the first voltage waveform at the first biasing electrode and the second voltage waveform at the second biasing electrode, wherein dechucking comprises: applying a fourth bias voltage to the first biasing electrode and applying a fifth bias voltage to the second biasing electrode by use of the one or more direct-current voltage supplies, wherein a magnitude of the fourth bias voltage and a magnitude of the fifth bias voltage are less than a magnitude of the third bias voltage or equal to zero. In some cases, the fourth bias voltage and the fifth bias voltage are less than the third bias voltage and greater than zero.

The plasma processing method can further include generating a plasma in the processing region of a plasma processing chamber for a third period of time, wherein the second period of time and the third period of time overlap in time. The process of generating the plasma in the processing region can further comprise biasing, by use of a direct current (DC) power source, a target positioned over the substrate supporting surface.

The plasma processing method can further include delivering a flow of gas to a space formed between the substrate supporting surface and the substrate that is electrostatically chucked to the substrate supporting surface during the first period of time; and electrostatically chucking the substrate to the substrate supporting surface for a third period of time by applying a fourth bias voltage to the first biasing electrode and the second biasing electrode by use of the one or more direct-current voltage supplies, wherein the third period of time is disposed between the first period of time and the second period of time, and the flow of gas delivered to the space formed between the substrate supporting surface and the substrate is halted during the third period of time.

Embodiments of disclosure include a processing chamber comprising a substrate-support assembly; a pulsed voltage generator electrically coupled to a first biasing electrode and a second biasing electrode, wherein an output node of the pulsed voltage generator is electrically coupled to the first biasing electrode through a first electrical conductor, and the output node of the pulsed voltage generator is electrically coupled to the second biasing electrode through a second electrical conductor. The processing chamber can also include a first direct-current voltage supply coupled to the first electrical conductor and between the first electrical conductor and a first node; and a second direct-current voltage supply coupled to the second electrical conductor and between the second electrical conductor and the first node, wherein the first node is electrically coupled to the output node of the pulsed voltage generator through a blocking capacitor. The first direct-current voltage supply, of the processing chamber assembly, is configured to provide a first voltage having a first polarity to the first electrical conductor, and the second direct-current voltage supply is configured to provide a second voltage having a second polarity to the second electrical conductor, wherein the first polarity is opposite to the second polarity. The processing chamber can also include a direct current (DC) power source that is configured to apply a voltage to a target, wherein applying a voltage to the target is configured to generate a plasma over a substrate supporting surface of the substrate support.

The following claims are not intended to be limited to the embodiments provided but rather are to be accorded the full scope consistent with the language of the claims.

What is claimed is:

1. A processing chamber assembly, comprising:
a chamber comprising a substrate-support assembly;
a pulsed voltage generator comprising an output connection that is electrically coupled to a plurality of biasing electrodes embedded within the substrate-support assembly; and
one or more chucking modules, wherein each chucking module of the one or more chucking modules comprises a direct-current voltage supply that is electrically coupled to one of the plurality of biasing electrodes through a corresponding bias compensation module that comprises a plurality of passive electrical components.

2. The processing chamber assembly of claim 1, wherein each of the biasing electrodes is coupled to an output of the pulsed voltage generator through an electrical conductor and a blocking capacitor.

3. The processing chamber assembly of claim 2, wherein each of the bias compensation modules and direct-current voltage supplies of the one or more chucking modules is electrically coupled to the corresponding electrical conductor at a first point between the corresponding blocking capacitor and the corresponding biasing electrode.

4. The processing chamber assembly of claim 3, further comprising a bypass resistor, wherein the bypass resistor is coupled between ground and the output connection of the pulsed voltage generator.

5. The processing chamber assembly of claim 3, further comprising:
a data acquisition system coupled to the electrical conductor at a second point between the blocking capacitor and the biasing electrode of the plurality of biasing electrodes, wherein a voltage divider is electrically coupled between an input of the data acquisition system and the second point.

6. The processing chamber assembly of claim 3, wherein the plurality of passive electrical components comprises a diode, a plurality of resistors, and a capacitor, wherein the diode and the capacitor are connected in series and coupled between ground and the first point on the electrical conductor.

7. The processing chamber assembly of claim 1, wherein the one or more chucking modules comprise:
a first chucking module that comprises a first direct-current voltage supply that is electrically coupled to a first biasing electrode of the plurality of biasing electrodes through a first bias compensation module; and
a second chucking module that comprises a second direct-current voltage supply that is electrically coupled to a second biasing electrode of the plurality of biasing electrodes through a second bias compensation module.

8. The processing chamber assembly of claim 7, wherein
the first direct-current voltage supply is configured to provide a first voltage having a first polarity to the first biasing electrode, and
the second direct-current voltage supply is configured to provide a second voltage having a second polarity to the second biasing electrode,
wherein the first polarity is opposite to the second polarity.

9. The processing chamber assembly of claim 1, further comprising:
a direct current (DC) power source that is configured to apply a voltage to a target, wherein applying the voltage to the target is configured to generate a plasma over a substrate supporting surface of the substrate support.

10. A plasma processing method, comprising:
electrostatically chucking a substrate to a substrate supporting surface of a substrate support for a first period of time by applying a first bias voltage to a first biasing electrode and applying a second bias voltage to a second biasing electrode by use of one or more direct-current voltage supplies, wherein
the first bias voltage and the second bias voltage are different,
the substrate supporting surface is disposed within a processing region of a processing chamber, and
the first biasing electrode and the second biasing electrode are disposed within the substrate support;
electrostatically chucking the substrate to the substrate supporting surface for a second period of time by applying a third bias voltage to the first biasing electrode and the second biasing electrode by use of the one or more direct-current voltage supplies; and
establishing a first voltage waveform at the first biasing electrode and a second voltage waveform at the second biasing electrode while the third bias voltage is applied to the first biasing electrode and the second biasing electrode.

11. The plasma processing method of claim 10, further comprising:
generating a plasma in the processing region of the processing chamber for a third period of time, wherein the second period of time and the third period of time overlap in time.

12. The plasma processing method of claim 11, wherein generating the plasma in the processing region comprises biasing, by use of a direct current (DC) power source, a target positioned over the substrate supporting surface.

13. The plasma processing method of claim 10, further comprising offsetting the first voltage waveform and the second voltage waveform by one or more voltage values.

14. The plasma processing method of claim 10, further comprising dechucking the substrate after establishing the first voltage waveform at the first biasing electrode and the second voltage waveform at the second biasing electrode, wherein dechucking comprises:
applying a fourth bias voltage to the first biasing electrode and applying a fifth bias voltage to the second biasing electrode by use of the one or more direct-current voltage supplies, wherein a magnitude of the fourth bias voltage and a magnitude of the fifth bias voltage are less than a magnitude of the third bias voltage or equal to zero.

15. The plasma processing method of claim 14, wherein the fourth bias voltage and the fifth bias voltage are less than the third bias voltage and greater than zero.

16. The plasma processing method of claim 10, further comprising:
delivering a flow of gas to a space formed between the substrate supporting surface and the substrate that is electrostatically chucked to the substrate supporting surface during the first period of time; and
electrostatically chucking the substrate to the substrate supporting surface for a third period of time by applying a fourth bias voltage to the first biasing electrode and the second biasing electrode by use of the one or more direct-current voltage supplies, wherein
the third period of time is disposed between the first period of time and the second period of time, and
the flow of gas delivered to the space formed between the substrate supporting surface and the substrate is halted during the third period of time.

17. The plasma processing method of claim 16, further comprising:
delivering a flow of gas to the space formed between the substrate supporting surface and the substrate that is electrostatically chucked to the substrate supporting surface during the second period of time.

18. A processing chamber assembly, comprising:
a chamber comprising a substrate-support assembly;
a pulsed voltage generator electrically coupled to a first biasing electrode and a second biasing electrode, wherein
an output node of the pulsed voltage generator is electrically coupled to the first biasing electrode through a first electrical conductor, and
the output node of the pulsed voltage generator is electrically coupled to the second biasing electrode through a second electrical conductor; and
a first direct-current voltage supply coupled to the first electrical conductor and between the first electrical conductor and a first node; and
a second direct-current voltage supply coupled to the second electrical conductor and between the second electrical conductor and the first node,
wherein the first node is electrically coupled to the output node of the pulsed voltage generator through a blocking capacitor.

19. The processing chamber assembly of claim 18, wherein
the first direct-current voltage supply is configured to provide a first voltage having a first polarity to the first electrical conductor, and
the second direct-current voltage supply is configured to provide a second voltage having a second polarity to the second electrical conductor,
wherein the first polarity is opposite to the second polarity.

20. The processing chamber assembly of claim 18, further comprising:
a direct current (DC) power source that is configured to apply a voltage to a target, wherein applying the voltage to the target is configured to generate a plasma over a substrate supporting surface of the substrate support.
